(19) United States
(12) Patent Application Publication
(10) Pub. No.: US 2011/0168232 A1
(43) Pub. Date: Jul. 14, 2011

(54) Method and System for Providing Tracking for Concentrated Solar Modules

(75) Inventors: Kevin Gibson, Redwood City, CA (US); Richard Martin, Livermore, CA (US)

(73) Assignee: Solaria Corporation, Fremont, CA (US)

(21) Appl. No.: 12/687,789

(22) Filed: Jan. 14, 2010

(51) Int. Cl. H01L 31/042

(52) U.S. Cl. 136/246

(57) ABSTRACT

According to an embodiment, the present invention provides a system for collecting solar energy. The system includes a solar panel, the solar panel comprising a plurality of photovoltaic strips, the plurality of photovoltaic strips including a first strip and a second strip, the first strip and the second strip being substantially parallel to each other, the plurality of photovoltaic strips being electrically coupled to one another, the solar panel including a front cover member, the front cover member including a plurality of concentrator elements, the plurality of photovoltaic strips being aligned to the plurality of concentrator elements, the plurality of concentrator elements including a first concentrator element and a second concentrator element, the first concentrator element and the second concentrator element being separated by a notch, the first concentrator being associated with a first angle and a second angle,

### BACKGROUND OF THE INVENTION

The present application relates generally to a tracking system for solar panels. More specifically, embodiments of the present invention provide tracking systems that are suitable for solar panels that include concentrator elements. In a specific embodiment, a tracking system according to the present invention selects from two or more angles for solar panels facing the sun, where at a first angle a solar region receives light from one concentrator element, and at a second angle the solar region receives light from a different concentrator element. In various embodiments, solar panels rotate to angles that minimize shadowing. There are other embodiments as well.

As the population of the world increases, industrial expansion has lead to an equally large consumption of energy. Energy often comes from fossil fuels, including coal and oil, hydroelectric plants, nuclear sources, and others. As an example, the International Energy Agency projects further increases in oil consumption, with developing nations such as China and India accounting for most of the increase. Almost every element of our daily lives depends, in part, on oil, which is becoming increasingly scarce. As time further progresses, an era of “cheap” and plentiful oil is coming to an end. Accordingly, other and alternative sources of energy have been developed.

Concurrent with oil, we have also relied upon other very useful sources of energy such as hydroelectric, nuclear, and the like to provide our electricity needs. As an example, most of our conventional electricity requirements for home and business use come from turbines run on coal or other forms of fossil fuel, nuclear power generation plants, and hydroelectric plants, as well as other forms of renewable energy. Often times, home and business use of electrical power has been stable and widespread.

Most importantly, much if not all of the useful energy found on the Earth comes from our sun. Generally all common plant life on the Earth achieves life using photosynthesis processes from sun light. Fossil fuels such as oil were also developed from biological materials derived from energy associated with the sun. For human beings including “sun worshipers,” sunlight has been essential. For life on the planet Earth, the sun has been our most important energy source and fuel for modern day solar energy.

Solar energy possesses many characteristics that are very desirable! Solar energy is renewable, clean, abundant, and often widespread. Certain technologies have been developed to capture solar energy, concentrate it, store it, and convert it into other useful forms of energy.

Solar panels have been developed to convert sunlight into energy. As an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successfully for certain applications, there are still limitations. Often, solar panels are unable to convert energy at their full potential due to the fact that the sun is often at an angle that is not optimum for the solar cells to receive solar energy. In the past, various types of conventional solar tracking mechanisms have been developed. Unfortunately, conventional solar tracking techniques are often inadequate. These and other limitations are described throughout the present specification, and may be described in more detail below.

From the above, it is seen that techniques for improving solar systems are highly desirable.

### BRIEF SUMMARY OF THE INVENTION

The present application relates generally to a tracking system for solar panels. More specifically, embodiments of the present invention provide tracking systems that are suitable for solar panels that include concentrator elements. In a specific embodiment, a tracking system according to the present invention selects from two or more angles for solar panels facing the sun, where at a first angle a solar region receives light from one concentrator element, and at a second angle the solar region receives light from a different concentrator element. In various embodiments, solar panels rotate to angles that minimize shadowing. There are other embodiments as well.

According to an embodiment, the present invention provides a system for collecting solar energy. The system includes a solar panel, the solar panel comprising a plurality of photovoltaic strips, the plurality of photovoltaic strips including a first strip and a second strip, the first strip and the second strip being substantially parallel to each other, the plurality of photovoltaic strips being electrically coupled to one another, the solar panel including a front cover member, the front cover member including a plurality of concentrator elements, the plurality of photovoltaic strips being aligned to the plurality of concentrator elements, the plurality of concentrator elements including a first concentrator element and a second concentrator element, the first concentrator element and the second concentrator element being separated by a notch, the first concentrator being associated with a first angle and a second angle, the first concentrator being configured to transmit electromagnetic waves received at the first angle to the first photovoltaic strip, the first concentrator being configured to transmit electromagnetic waves received at the second angle to the second photovoltaic strip, the second concentrator being configured to transmit electromagnetic waves received at the first angle to the second photovoltaic strip. The system also includes a sensor for determining a position for a light source. The system further includes a motion control module for selecting a third angle for receiving electromagnetic waves from the light source, the third angle being selected between the first angle and the second angle. Also, the system includes a motor module configured for rotating the solar panel for facing the light source at the third angle.

According to another embodiment, the present invention provides a system for collecting solar energy. The system includes a solar array comprising a first solar panel and a second solar panel, the first solar panel being at a predetermined distance from the second solar panel. The system also includes a solar panel, the solar panel comprising a plurality of photovoltaic strips, the plurality of photovoltaic strips including a first strip and a second strip, the first strip and the second strip being substantially parallel to each other, the plurality of photovoltaic strips being electrically coupled to one another, the solar panel including a front cover member, the front cover member including a plurality of concentrator elements, the plurality of photovoltaic strips being aligned to the plurality of concentrator elements, the plurality of concentrator elements including a first concentrator element and a second concentrator element, the first concentrator element and the second concentrator element being separated by a notch, the first concentrator element being associated with a first angle and a second angle, the first concentrator being configured to transmit electromagnetic waves received at the first angle to the first photovoltaic strip, the first concentrator being configured to transmit electromagnetic waves received at the second angle to the second photovoltaic strip, the second concentrator being configured to transmit electromagnetic waves received at the first angle to the second photovoltaic strip. The system additional includes a motion control module for determining a position for a light source and selecting a third angle for receiving electromagnetic waves from the light source, the third angle being selected between the first angle and the second angle. The system also includes a first motor module configured for rotating the first solar panel for facing the light source at the third angle.

Various additional objects, features and advantages of the present invention can be more fully appreciated with reference to the detailed description and accompanying drawings that follow.

### BRIEF DESCRIPTION OF THE DRAWINGS

FIG. 1A is a simplified diagram illustrating the operation of a conventional solar tracking system.

FIG. 1B is a simplified diagram illustrating a conventional solar tracking system operating around the noon time.

FIG. 1C is a simplified diagram illustrating a conventional back tracking system.

FIG. 2A is a simplified diagram illustrating a solar panel according to an embodiment of the present invention.

FIG. 2B is a simplified diagram illustrating a solar concentrator element as a part of a solar panel according to an embodiment of the present invention.

FIG. 2C is a simplified diagram providing an exploded view of a concentrated solar panel according to an embodiment of the present invention.

FIG. 3 is a simplified diagram illustrating a solar concentrator according to an embodiment of the present invention.

FIG. 4A is a simplified diagram illustrating a solar concentrator according to an embodiment of the present invention.

FIG. 4B is a simplified diagram illustrating the operation of a solar panel with solar concentrator according to an embodiment of the present invention.

FIGS. 5A and 5B are simplified diagrams illustrating the light path of a concentrated solar module according to an embodiment of the present invention.

FIG. 6 is a simple diagram illustrating the light path for a concentrated solar panel according to an embodiment of the present invention.

FIG. 7 is a simplified diagram illustrating a result for concentrated solar modules according to an embodiment of the present invention.

FIGS. 8A and 8B are simplified diagrams showing simulation of the light path of a concentrated solar module according an embodiment of the present invention. These diagrams are merely examples, which should not unduly limit the scope of the claims.

FIGS. 9A and 9B are simplified diagrams illustrating various solar array angles according embodiments of the present invention.

FIG. 10 is a simplified diagram illustrating a relationship between tracking and time according to an embodiment of the present invention.

### DETAILED DESCRIPTION OF THE INVENTION

The present application relates generally to a tracking system for solar panels. More specifically, embodiments of the present invention provide tracking systems that are suitable for solar panels that include concentrator elements. In a specific embodiment, a tracking system according to the present invention selects from two or more angles for solar panels facing the sun, where at a first angle a solar region receives light from one concentrator element, and at a second angle the solar region receives light from a different concentrator element. In various embodiments, solar panels rotate to angles that minimize shadowing. There are other embodiments as well.

As discussed above, conventional tracking systems for solar panels are available but are often inadequate. More specifically, where tight juxtaposition of solar panels are required (e.g., solar panel arrays), conventional tracking systems are often incapable of efficiently utilizing both space and solar energy. For example, conventional tracking mechanisms involve simply following the movement of the sun. There are four basic types of tracking mechanisms: (1) seasonal (e.g., moving once a quarter); (2) single axis horizontal; (3) single axis tilted; (4) dual axis tracking; (5) polar axis tracking; and others. When land is free and plentiful, trackers are spaced such that they can never shadow each other. When land is costly or limited, then systems are installed such that in the morning and evening it is possible for one tracker to shadow the one behind it. To avoid shadowing, trackers typically stop following the sun and instead move to positions that are as close as possible to the sun without causing any shading. This is referred to as back-tracking. Unfortunately, small amounts of shading are enough to stop most of the energy generation.

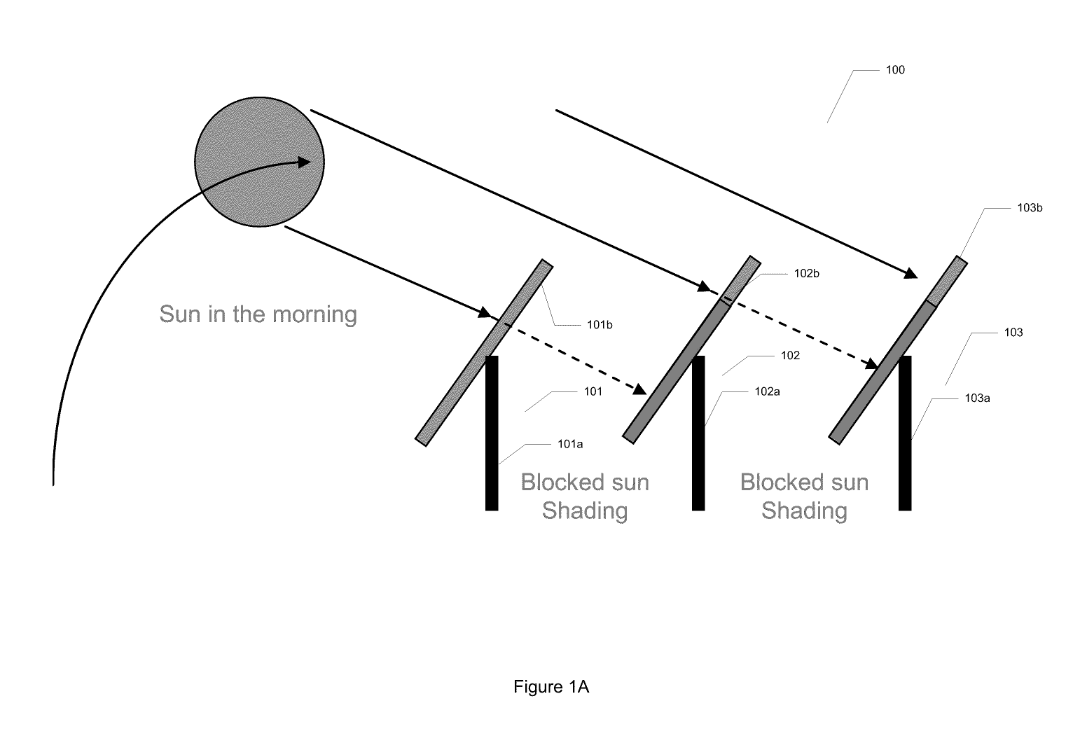

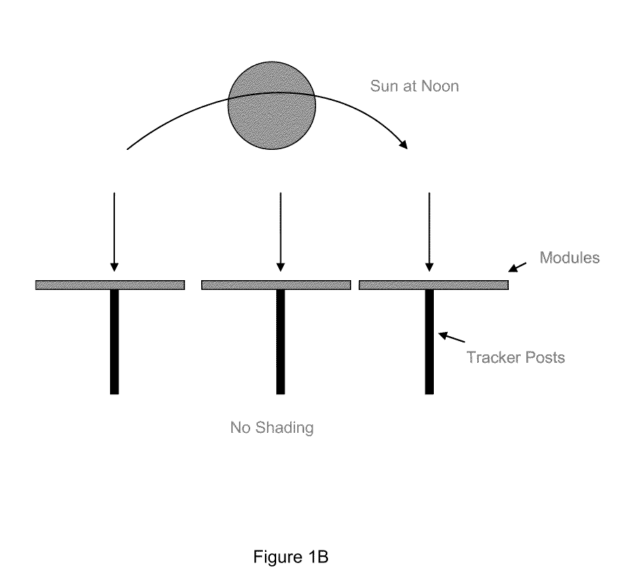

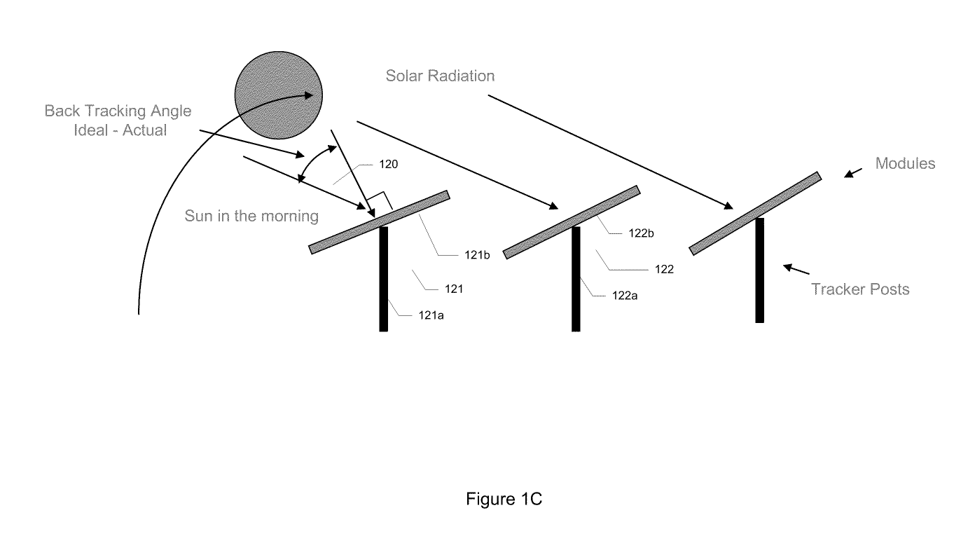

FIG. 1A is a simplified diagram illustrating the operation of a conventional solar tacking system. As shown in FIG. 1A, a solar array 100 comprises solar panel systems 101, 102 and 103. Each of the solar systems comprises a solar module and a tracker post. For example, the solar panel system 101 comprises a solar module 101b for receiving and converting solar energy. The tracking post 101a is a part of the solar panel system 101 that supports the solar module 101b and is configured to track the sun so that the solar module 101b is continuously facing the sun at an angle optimized for energy capture and conversion (e.g., the sun light reaching the surface of the solar module 101b at an angle of about 90 degrees). As shown in FIG. 1A, the solar module 101b is rotated to an angle by the tracking post 101a so that the surface of the solar module 101b is facing the sun at an angle of approximate 90 degrees. For example, the solar modules are rotated to the angle illustrated in FIG. 1A when the sun is low in the sky (e.g., morning and/or evening).

Shading is one of the problems associated with the conventional solar tracking system illustrated in FIG. 1A. As shown, while the full surface area of solar module 101b is optimized for collecting and converting light from the sun, the position and angle of solar module 101a creates shade that blocks an area of solar module 102b, which is positioned, relative to the morning sun, behind solar module 101a. Similarly, solar module 102b blocks an area of solar module 103b. The blocked areas of the solar modules receive less light (e.g., receiving diffused and/or reflected light) than solar module areas receiving direct sunlight. As a result of shading, energy capture and conversion becomes inefficient for the solar array 100, despite the presence of the conventional tracking system.

The shading problem, described above for the conventional solar tracking system illustrated in FIG. 1A, typically results in low energy conversion rate. For example, compared to solar array systems where no tracking mechanism is provided, the tracking system 100 still provides better energy conversion over period of time. The shading among the solar modules as illustrated in FIG. 1A is usually limited to tracking angles in the morning and evening.

FIG. 1B is a simplified diagram illustrating a conventional solar tracking system operating around the noon time. As shown, the sun around noon time is perpendicular to the surfaces of the solar modules and, as result, no shadowing occurs among the solar modules.

In a conventional arrangement, a shading problem is avoided by restricting the amount of movement of the tracking systems at certain times of the day. FIG. 1C is a simplified diagram illustrating a conventional back tracking system. As shown in FIG. 1C, as the sun is rising or setting, the tracking system avoids shadowing among the solar modules by restricting the solar module movements.

For example, when the sun is rising or setting, tracking post 121a positions the solar module 121b at an angle 120. At the angle 120, the solar module 121b is not facing the sun directly and does not create a shadow caste over solar module 122b. For example, the tracking mechanism of the conventional system goes toward a horizontal position until it is able to track without shading. Alternatively, the conventional system positions the solar module as close to the sun as possible without causing shading.

It is therefore to be appreciated that the present invention provides solar tracking techniques that allow for efficient energy capture using solar panels with concentrator elements, which are described below.

The tracking techniques according to the embodiments of the present invention are used in conjunction with solar panels with solar concentrator elements. This type of solar panel with solar concentrator elements is described in patent application Ser. No. ______, (Attorney Docket No. 025902-005710US), which is incorporated by reference herein for all purposes.

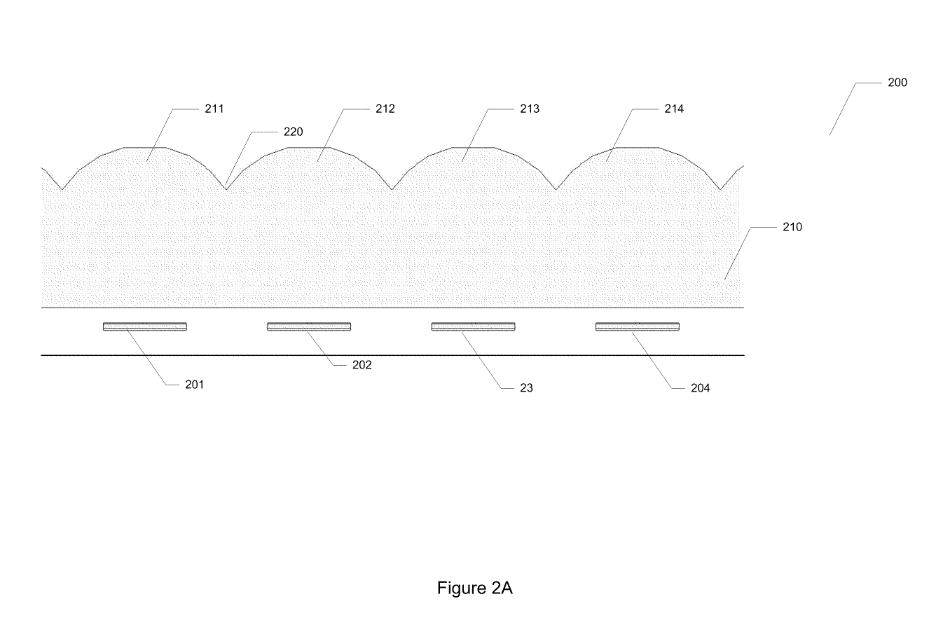

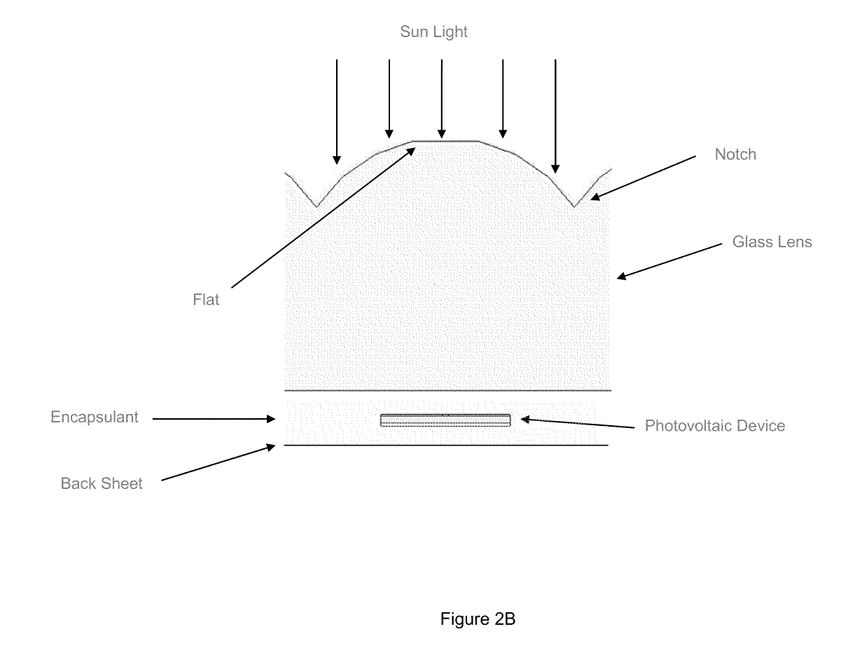

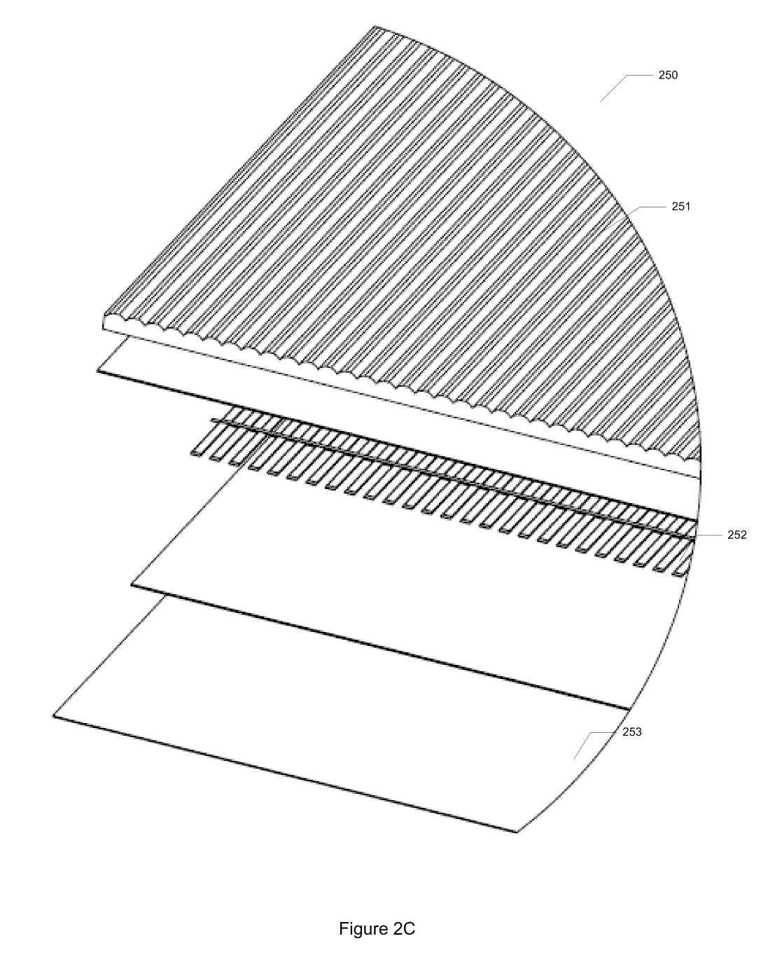

FIG. 2A is a simplified diagram illustrating a solar panel according to an embodiment of the present invention. This diagram is merely an example, which should not unduly limit the scope of the claims. One of ordinary skill in the art would recognize many variations, alternatives, and modifications. As shown in FIG. 2A, a solar panel 200 comprises a plurality of photovoltaic strips 201-204. The plurality of photovoltaic strips includes a first strip 201 and a second strip 202, the first strip and the second strip being substantially parallel to each other. The photovoltaic strips are electrically coupled to one another. For example, electrically conductive buses (not shown in FIG. 2A) are used to electrically couple photovoltaic strips. The solar panel includes a front cover member 210.

The front cover member includes a plurality of concentrator elements. The plurality of photovoltaic strips is aligned to the plurality of concentrator elements 211-214. The plurality of concentrator elements includes a first concentrator element 211 and a second concentrator element 212. The first concentrator element 211 and the second concentrator element 212 are separated by a notch 220. The first concentrator element 211 is associated with a first angle and a second angle. The first concentrator element 211 is configured to transmit electromagnetic waves received at the first angle to the first photovoltaic strip 201.

For example, the first concentrator element 211 is configured to transmit light to the photovoltaic strip 201 at a substantially perpendicular angle. The first concentrator element 211 is configured to transmit electromagnetic waves received at the second angle to the second photovoltaic strip 202. The second concentrator element 212 is configured to transmit electromagnetic waves received at the first angle to the second photovoltaic strip 202.

FIG. 2B is a simplified diagram illustrating a solar concentrator element as a part of a solar panel according to an embodiment of the present invention. This diagram is merely an example, which should not unduly limit the scope of the claims. One of ordinary skill in the art would recognize many variations, alternatives, and modifications. As shown in FIG. 2B, a photovoltaic device is held by an encapsulating material (e.g., EVA or others) and aligned with the concentrator element. For example, the concentrator element is made of glass.

FIG. 2C is a simplified diagram providing an exploded view of a concentrated solar panel according to an embodiment of the present invention. This diagram is merely an example, which should not unduly limit the scope of the claims. One of ordinary skill in the art would recognize many variations, alternatives, and modifications. As shown in FIG. 2C, a concentrated solar panel 250 includes a concentrator 251, a photovoltaic assembly 252, and a back cover member 253. For example, the components of the concentrated solar panel 250 are coupled together by encapsulating material.

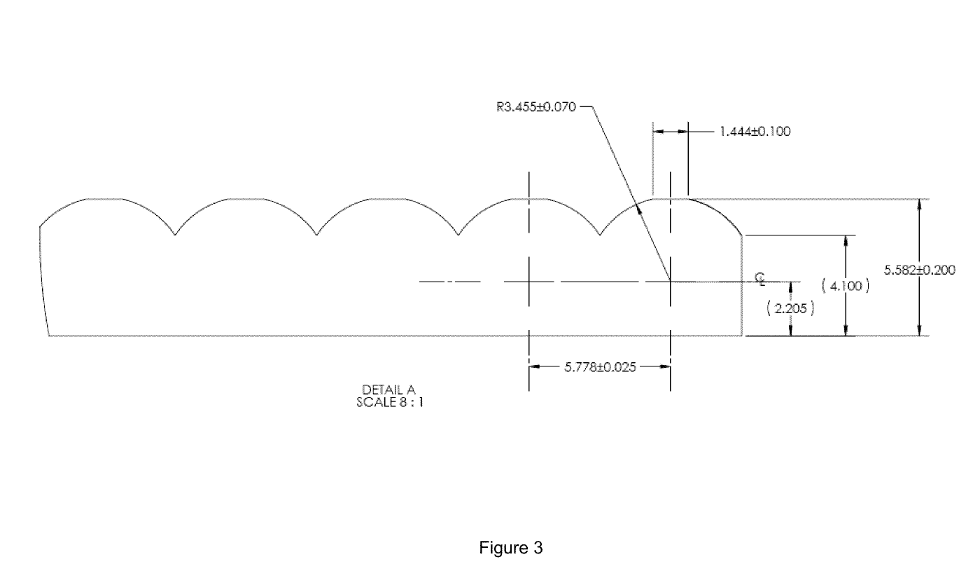

FIG. 3 is a simplified diagram illustrating a solar concentrator according to an embodiment of the present invention. This diagram is merely an example, which should not unduly limit the scope of the claims. One of ordinary skill in the art would recognize many variations, alternatives, and modifications. As an example, dimensions of the solar concentrator (in mm) are provided. For example, each concentrator has a width of 5.778 mm with a tolerance of 0.025 mm. It is to be appreciated that other dimensions and geometrical shapes may be used as well. As an example, the numerical dimensions shown are in millimeters for the concentrator element. Depending on the application, the solar concentrator as shown may be scaled up or down. For example, a solar concentrator may be characterized by a surface area of over 1 m², and a number of concentrator elements with dimensions shown in FIG. 1B occupy essentially the entire area of the solar concentrator.

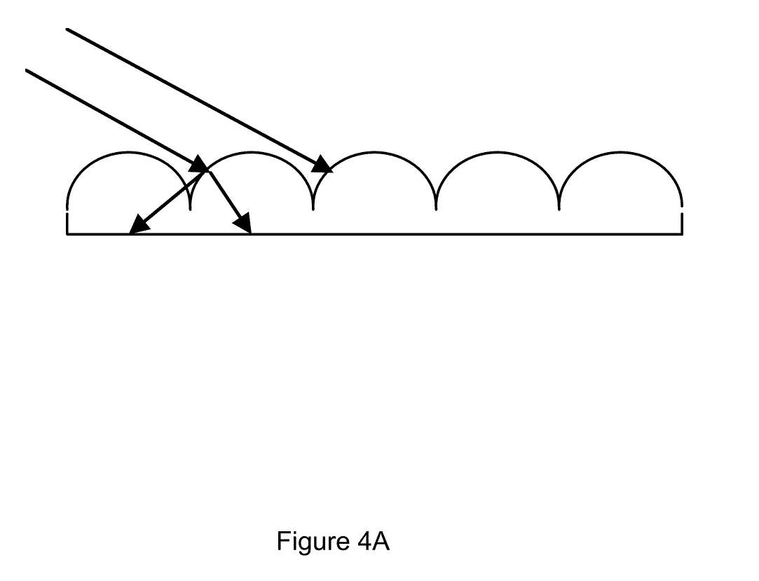

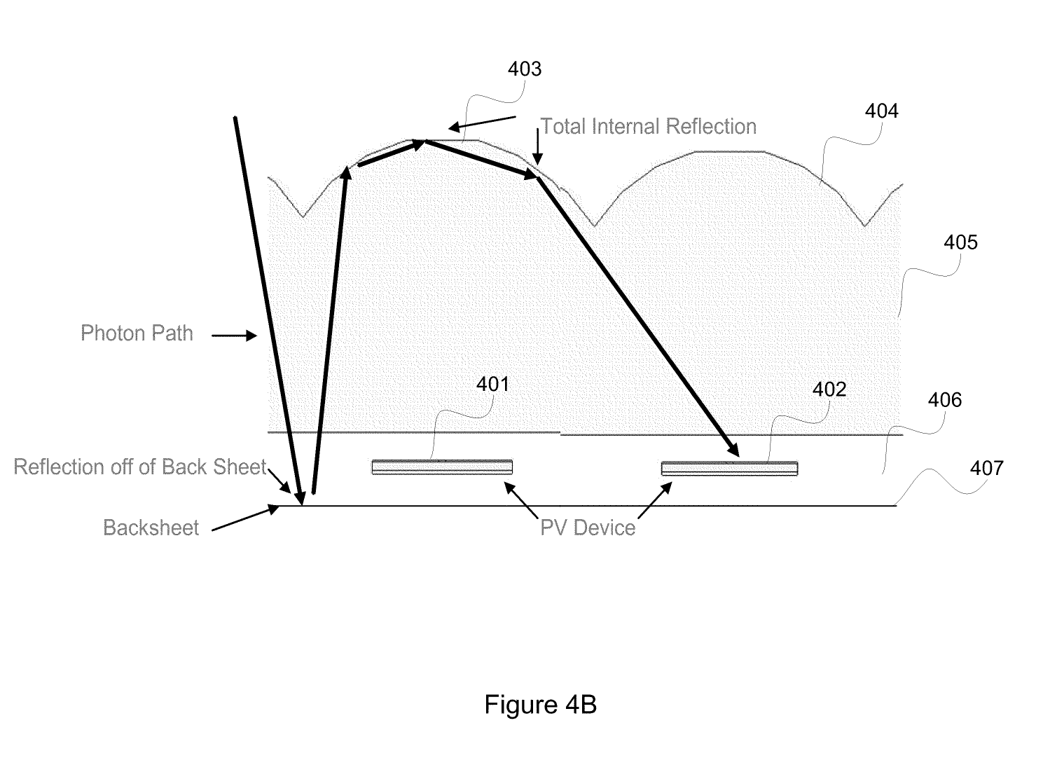

FIG. 4A is a simplified diagram illustrating a solar concentrator according to an embodiment of the present invention. This diagram is merely an example, which should not unduly limit the scope of the claims. One of ordinary skill in the art would recognize many variations, alternatives, and modifications. As shown in FIG. 4A, light incident to a concentrator element occurring at a steep angle is directed to two different locations, both of which can be collected by a photovoltaic region underneath. It is to be appreciated that with off angle light occurring at steep angles across the length of the optics of the concentrator module, more light enters a solar module when compared with a conventional solar module at the same angle.

The steep angles of incidence with flat glass allow for large Fresnel reflections. The curved shape of the concentrator means that there are always surface areas that are substantially normal to the light. Additionally, the concentrator structure as shown allows the reflected light an opportunity to re-enter the solar module and to be collected by the photovoltaic region underneath.

FIG. 4B is a simplified diagram illustrating the operation of a solar panel with solar concentrator according to an embodiment of the present invention. This diagram is merely an example, which should not unduly limit the scope of the claims. One of ordinary skill in the art would recognize many variations, alternatives, and modifications.

As shown in FIG. 4B, a solar concentrator 405 comprises solar concentrator elements 403 and 404. The concentrator elements 403 and 404 are characterized by a curved shape, with a flat region at the top. It is to be appreciated that the geometric shape of the concentrator elements is optimized for light gathering. Photovoltaic strips 401 and 402 are respectively aligned to the solar concentrators 403 and 404 as shown in FIG. 4B. For example, the photovoltaic strips are part of the electrically connected photovoltaic package. A reflective back sheet 407 is provided as shown. In various embodiments, the photovoltaic strips 401 and 402 are secured between the back sheet 407 and the solar concentrator 405 using coupling material 406. For example, the coupling material comprises EVA material.

The shape of the concentrators and their alignment with the photovoltaic strips is optimized to allow the photovoltaic strips to capture as much photovoltaic energy as possible. As shown in FIG. 4B, a photon that does not initially make its way to a photovoltaic strip is reflected by back sheet 407 to solar concentrator 403, and solar concentrator 403 reflects the photon to photovoltaic strip 402, which can capture the photon and generate energy.

It is to be appreciated that in various embodiments, solar concentrator 405 and back sheet 407 together allows for greater total internal reflection, thereby increasing the chances of the photon being captured by the photovoltaic strips. For example, stray light that misses the photovoltaic device is reflected from the back sheet. Much of the reflected back sheet light is then reflected (e.g., total internal reflection) within the module. Light will reflect around within the module until it either hits the photovoltaic strip and is converted to electricity, exits the module, or is absorbed in the glass, EVA, or back sheet.

It is to be appreciated that various embodiments of the present invention allow for optimized absorption of light and thereby better conversion. The internal reflection afforded by the device illustrated in FIG. 4B provides for one aspect of light capturing. However, while internal reflection redirects photons that did not reach a photovoltaic region in the first pass through, the light captured by the photovoltaic strip 402 is typically not as efficient as direct light captured (i.e., capturing photons in their first pass before any internal reflection). Thus, solar tracking mechanisms as provided by the embodiments of the present invention are used to improve solar panel efficiency.

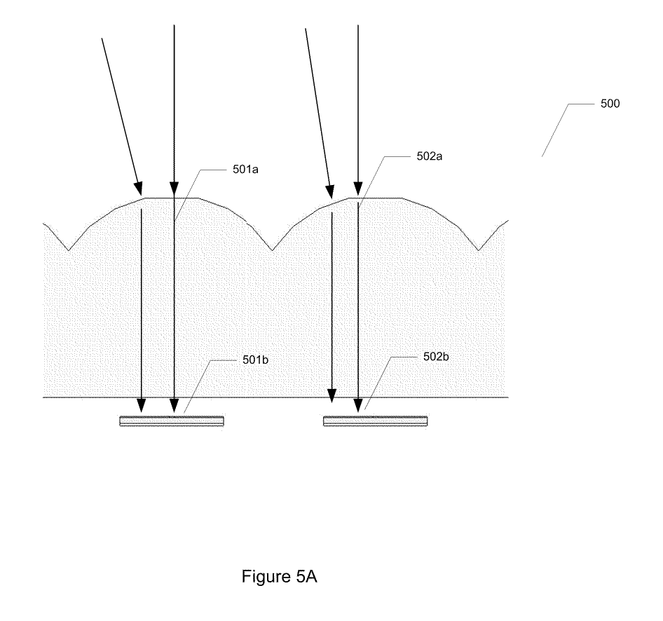

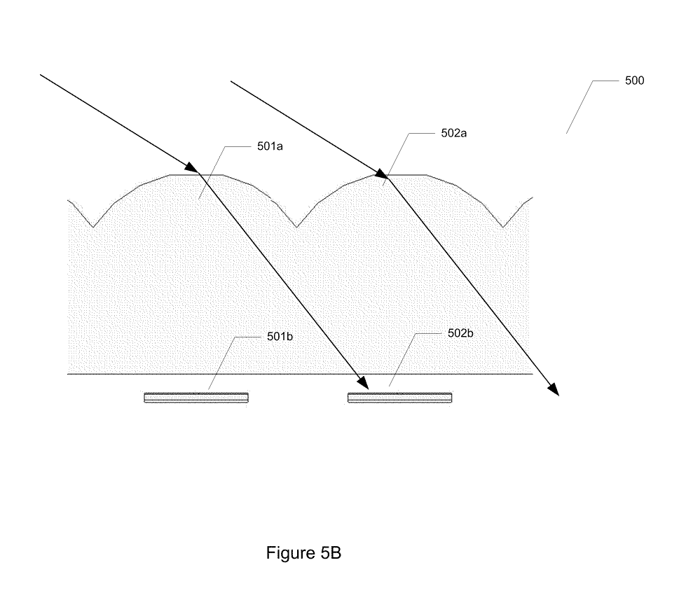

FIGS. 5A and 5B are simplified diagrams illustrating the light path of a concentrated solar module according to an embodiment of the present invention. These diagrams are merely examples, which should not unduly limit the scope of the claims. One of ordinary skill in the art would recognize many variations, alternatives, and modifications.

As shown in FIG. 5A, a solar module 500 includes concentrator elements 501 and 502. The concentrator elements 501a and 502a are aligned, respectively, directly above photovoltaic regions 501b and 502b. For example, light reaching the concentrator element 501a is concentrated onto the photovoltaic strip 501b, which in turn converts the light to energy. Similarly, the concentrator element 502b directs the light it receives to the photovoltaic strip 502b underneath. Typically, when the concentrator elements receive light at a normal angle (e.g., light entering at a right angle) or when the angle of light is relatively close to the normal angle, most of the light received by the concentrator elements is directed to the photovoltaic strips. As illustrated in FIG. 5A, when light enters at a slight angle (off the direct perpendicular angle), the light still reaches the photovoltaic strips 501b and 502b below.

It is to be appreciated that the concentrated solar devices according to embodiments of the present invention are able to efficiently capture solar energy at different angles. More specifically, a concentrator element is able to direct light to a first photovoltaic region at a right angle and direct light to a second photovoltaic region at a steep angle. In FIG. 5B, light reaches the concentrator element 501a at a steep angle, and the concentrator element 501a directs light to the photovoltaic strip 502b. In the same way, the photovoltaic strip 501b receives light not from the concentrator element 501a that is directly aligned above it, but from an adjacent concentrator element. The concentrator element 502a, when receiving light at a steep angle, directs light not to the photovoltaic strip 502b, but to a different photovoltaic strip.

The ability to capture solar energy at different angles, one being a normal angle and the other steep angle, is used in various embodiments of the present invention, where tracking mechanisms align solar panels to face the sun at multiple angles where most of the light received by the solar concentrators are directed to photovoltaic regions. On the other hand, at some other angles, solar panels with concentrators according to embodiments of the present invention cannot efficiently capture light energy.

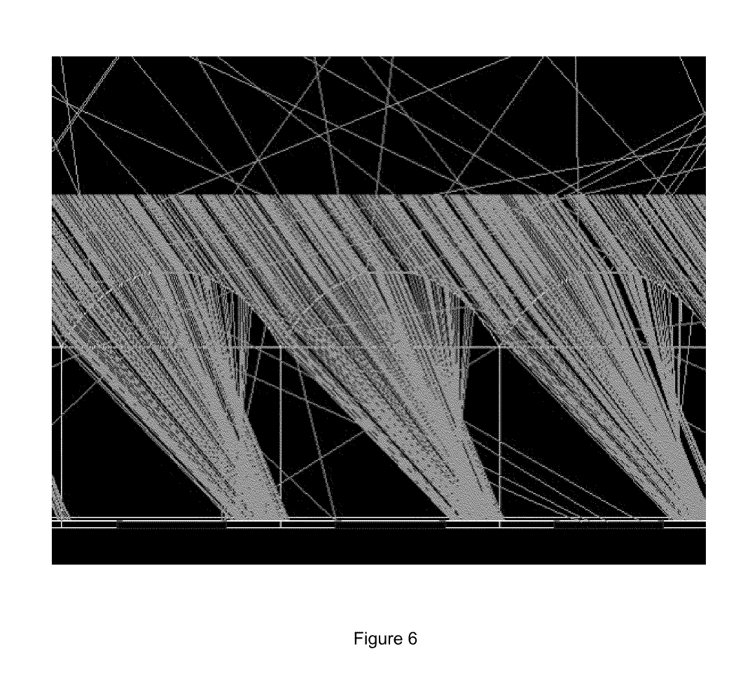

FIG. 6 is a simple diagram illustrating the light path for a concentrated solar panel according to an embodiment of the present invention. This diagram is merely an example, which should not unduly limit the scope of the claims. One of ordinary skill in the art would recognize many variations, alternatives, and modifications. As shown in FIG. 6, a large portion of light that reaches the concentrator elements is directed to a region between photovoltaic regions, thereby missing the targeted area. As described above, in various embodiments light capturing is possible through internal reflection, light not being directed to the photovoltaic region often poses a problem.

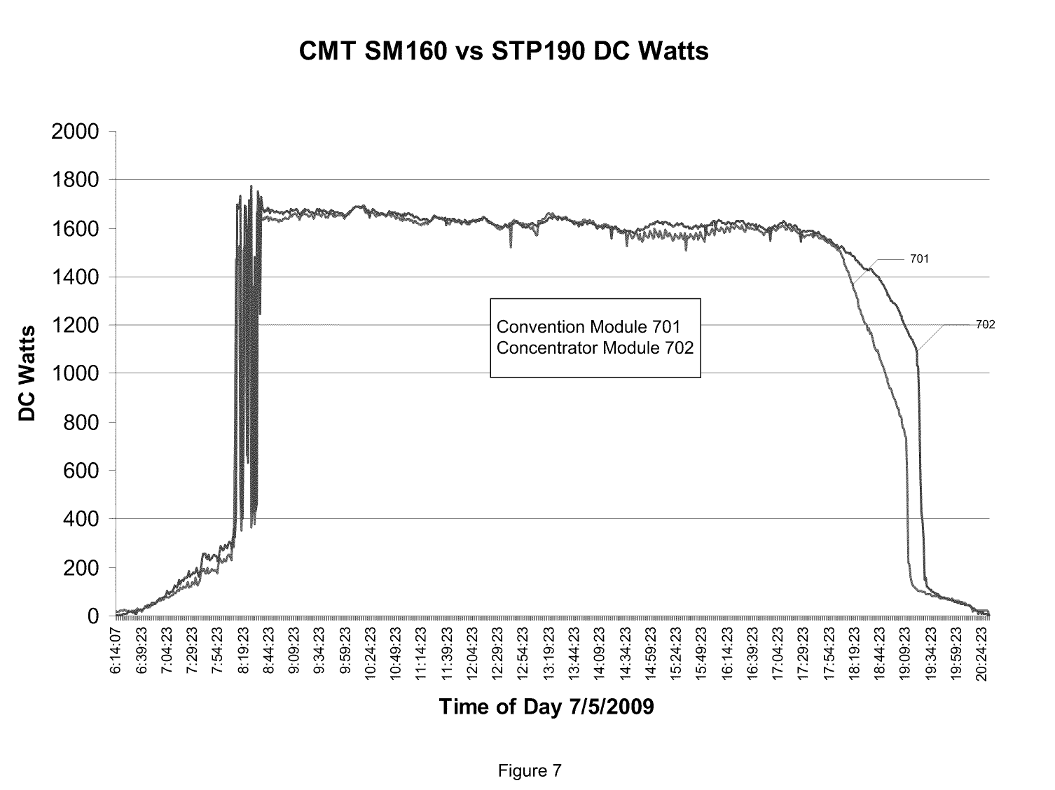

FIG. 7 is a simplified diagram illustrating a result for concentrated solar modules according to an embodiment of the present invention. This diagram is merely an example, which should not unduly limit the scope of the claims. One of ordinary skill in the art would recognize many variations, alternatives, and modifications. In FIG. 7, the graph shows how solar module performance falls faster than a normal module when tracking stops. For example, simulations show that the light will start to miss the photovoltaic device. As the angle increases more and more light misses the photovoltaic device and the performance continues to drop. In contrast, conventional back tracking and or horizontal positions will result in lower energy yields than a standard module. As shown, the curve 701 illustrates the output level of a tracking solar panel according an embodiment of the present invention. As a comparison, the curve 702 illustrates output level of conventional solar tracking module.

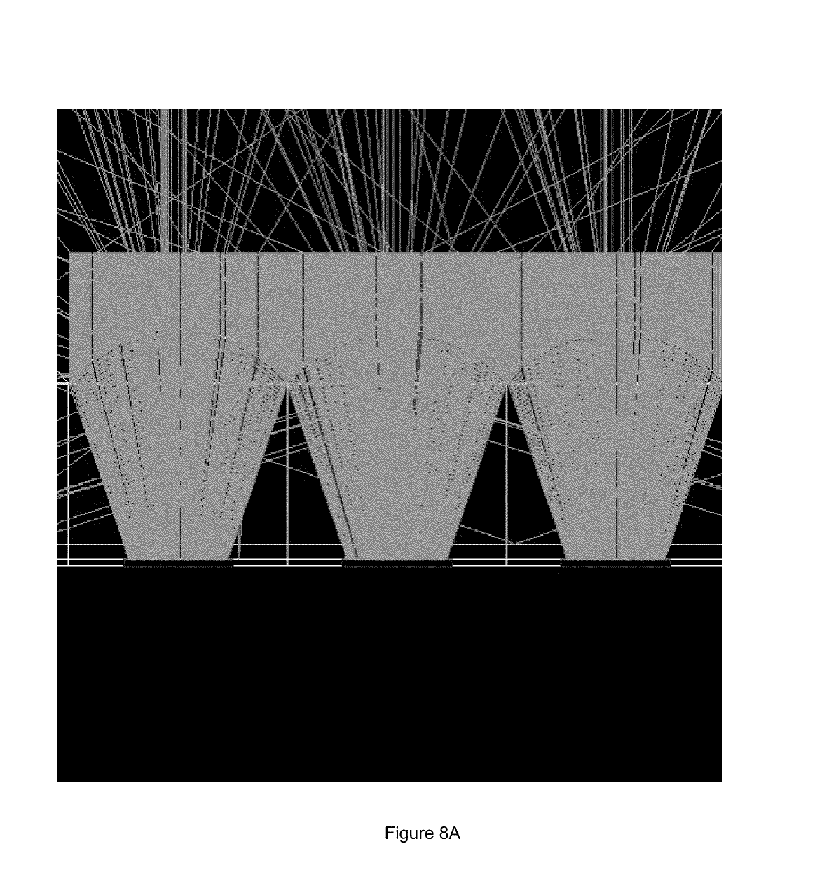

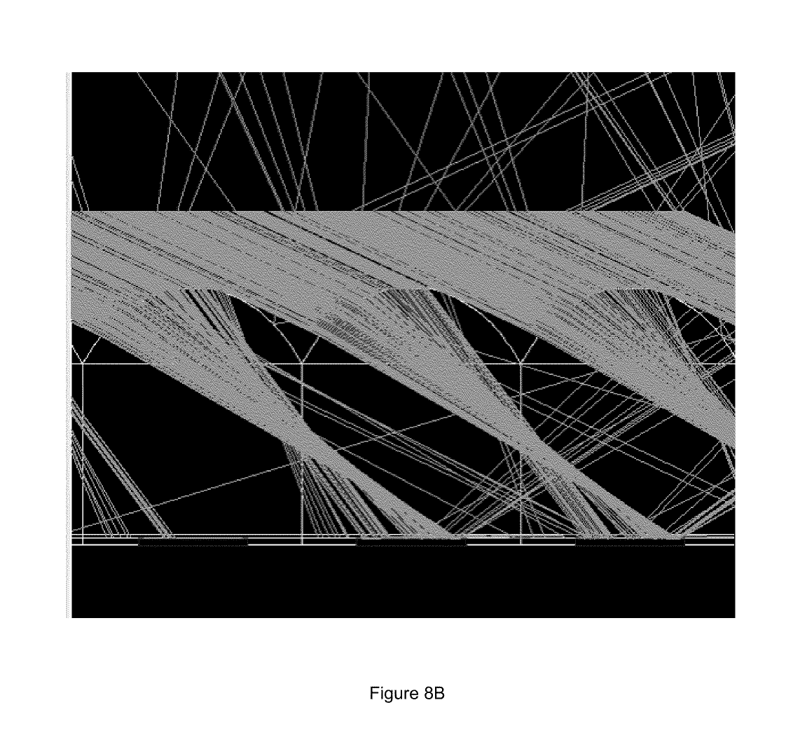

FIGS. 8A and 8B are simplified diagrams showing simulation of the light path of a concentrated solar module according an embodiment of the present invention. These diagrams are merely examples, which should not unduly limit the scope of the claims. One of ordinary skill in the art would recognize many variations, alternatives, and modifications. As shown in FIG. 8A, light reaching the solar panel at a substantially normal angle is redirected to the photovoltaic regions. FIG. 8B illustrates that light reaching the solar panel at a steep angle is redirected to the photovoltaic regions that are not directly aligned with concentrator elements.

According to various embodiments, the concentrator directs the light to the photovoltaic devices that are aligned directly under the lens. The tracker ensures that the module is aligned to the sun. Unique to the concentrated solar modules according to the embodiments of the present invention, there is another angle at which light can enter the module and land on a photovoltaic device adjacent to the lens where the light entered. A specific tracking profile is used to track the sun when there is no shadowing like a normal tracker. In one embodiment, when shadow occurs in the morning and evening, the concentrated solar modules would be positioned at an angle between 45 and 70 degrees to the sun. The modules would maintain the angle to the sun for as long as the modules remain shadow free or the sun is beyond the horizon.

According to various embodiments, various parameters are used in establishing a tracking profile. For example, these parameters include latitude, time of year, tracking limits, ground coverage ratio, etc. Ground coverage ratio (GCR) refers to the area occupied by the solar module at noon (i.e., when horizontal relative to the ground) relative to the amount of land coverage of the system. Many systems today are between 25% to 50% coverage with trackers that can move +/−45 degrees. As the ground coverage ratio increases, the effects of shadowing become more noticeable and thus the advantages of tracking go away.

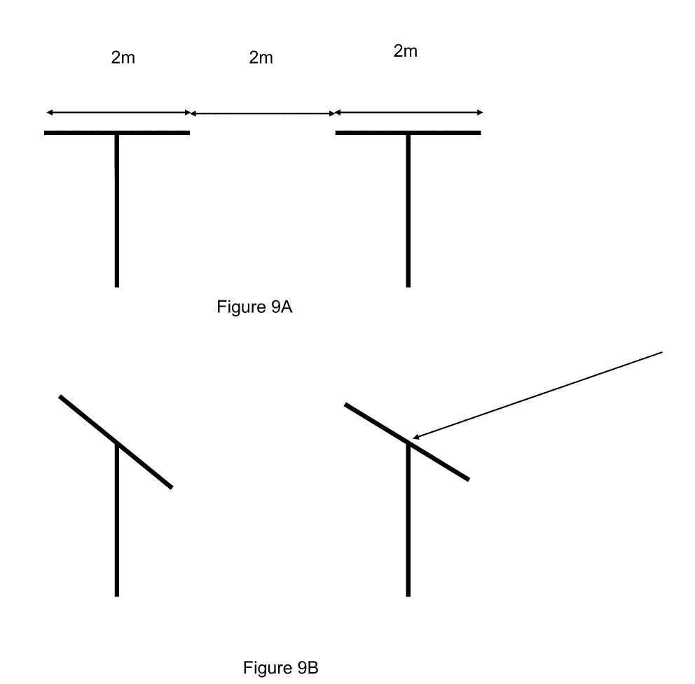

FIGS. 9A and 9B are simplified diagrams illustrating various solar array angles according embodiments of the present invention. More specifically, for example, in an ideal case, the ground coverage ratio is very close to zero. This way shadowing is almost a non-issue. For example, the tracker can move +/−90 degrees. As shown in FIG. 9A, the solar module will behave just like a regular module when the movement is not constrained. Unfortunately land is not free so almost nobody installs systems with a GCR near zero. For example, the GCR of zero is illustrated in FIGS. 9A and 9B.

When the ground coverage ratio increases, shadowing becomes a problem with trackers. Trackers usually backtrack to avoid shadowing. As they backtrack, they will incur losses due to the cosine error. The cosine losses are usually much less than the losses from shadowing.

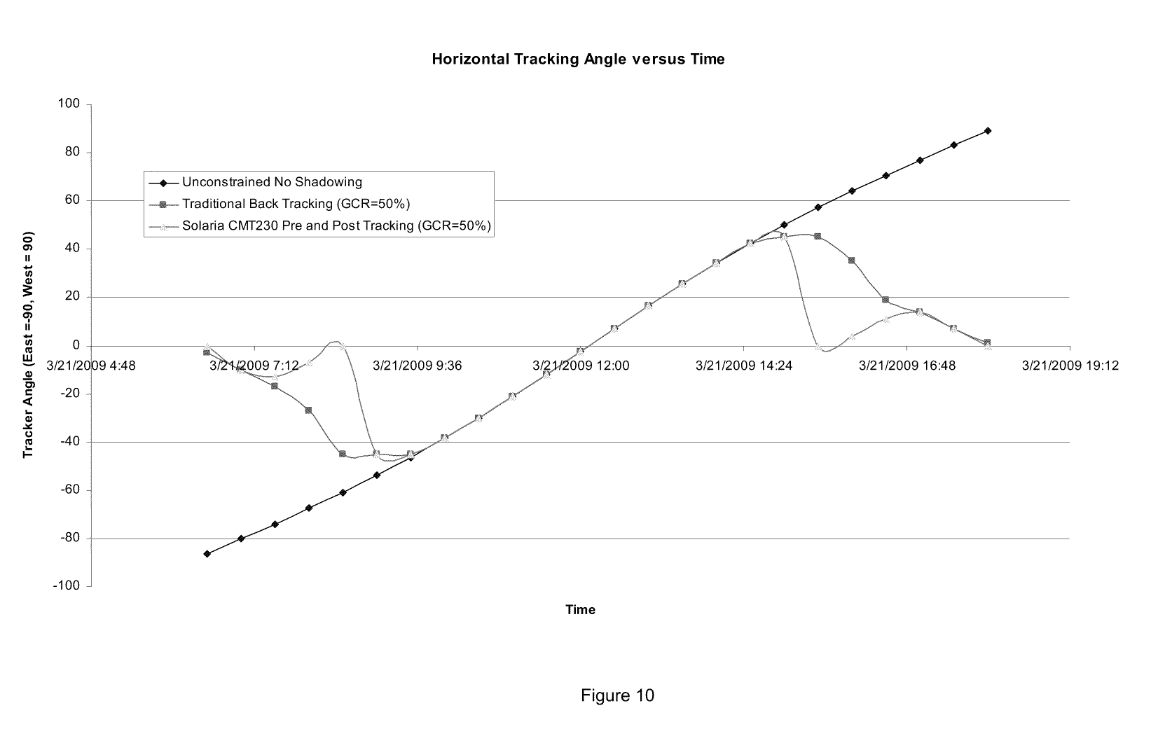

FIG. 10 is a simplified diagram illustrating a relationship between tracking and time according to an embodiment of the present invention. This diagram is merely an example, which should not unduly limit the scope of the claims. One of ordinary skill in the art would recognize many variations, alternatives, and modifications.

To illustrate shadowing and backtracking, a generic scenario is used for a single axis horizontal tracker located at 37 degrees north, 121 degrees west on March 21. The tracker can move +/−45 degrees and the ground coverage ratio is 50%. In this case the tracker stops at the limits (say +45 degrees in the afternoon) and will stay there for about an hour until shadowing starts. At that time the tracker has to start tracking in the other direction. Thus the name backtracking. This is shown as traditional backing tracking with GCR=50%.

For tracking with concentrated solar modules according to embodiments of the present invention, with the angle of incidence effects on our module, the tracking profile is designed to capitalize the ability of concentrated solar modules of capturing solar energy at more than one angle. For example, a tracking with “pre” and “post” settings are used: “pre” is in the morning, and “post” is in the afternoon. In this case, once we approach the area with the greatest losses (Point A) we will move the tracker until we get to the secondary acceptance angle. At this point the light will skip over one photovoltaic strip. Once we are at this point, we can continue to forward track until shadowing becomes an issue again.

As an example, the plot shown in FIG. 10 is generated using simulated data of Table 1, which is reproduced below:

TABLE 1

| Latitude | 37 | | |
|---|---|---|---|
| Longitude | 121 | | |
| Negative Angles | East Facing | | |
| Positive Angles | West Facing | | |
| | Array Tilt | | |
| | | | Solaria |
| | | Traditional Back | CMT230 Pre |
| | Unconstrained | Tracking | and Post Tracking |
| Time | No Shadowing | (GCR = 50%) | (GCR = 50%) |
| 3/21/2009 6:30 | −86.24 | −3 | 0 |
| 3/21/2009 7:00 | −80.17 | −10 | −10 |
| 3/21/2009 7:30 | −73.98 | −17 | −13 |
| 3/21/2009 8:00 | −67.57 | −27 | −7 |
| 3/21/2009 8:30 | −60.98 | −45 | 0 |
| 3/21/2009 9:00 | −53.83 | −45 | −45 |
| 3/21/2009 9:30 | −46.37 | −45 | −45 |
| 3/21/2009 10:00 | −38.43 | −38.43 | −38.43 |
| 3/21/2009 10:30 | −30.01 | −30.01 | −30.01 |
| 3/21/2009 11:00 | −21.14 | −21.14 | −21.14 |
| 3/21/2009 11:30 | −11.91 | −11.91 | −11.91 |
| 3/21/2009 12:00 | −2.44 | −2.44 | −2.44 |
| 3/21/2009 12:30 | 7.06 | 7.06 | 7.06 |
| 3/21/2009 13:00 | 16.43 | 16.43 | 16.43 |
| 3/21/2009 13:30 | 25.5 | 25.5 | 25.5 |
| 3/21/2009 14:00 | 34.14 | 34.14 | 34.14 |
| 3/21/2009 14:30 | 42.32 | 42.32 | 42.32 |
| 3/21/2009 15:00 | 50.01 | 45 | 45 |
| 3/21/2009 15:30 | 57.26 | 45 | 0 |
| 3/21/2009 16:00 | 64.11 | 35 | 4 |
| 3/21/2009 16:30 | 70.64 | 19 | 11 |
| 3/21/2009 17:00 | 76.92 | 14 | 14 |
| 3/21/2009 17:30 | 83.03 | 7 | 7 |
| 3/21/2009 18:00 | 89.04 | 1 | 0 |

It is to be appreciated that one unique aspect of the tracking mechanism according to the present invention is the backtracking profile. Conventional backtracking is smooth and continuous. Once a normal system stops tracking the sun, it will begin to track in the other direction. In contrast, according to the present invention, the tracking mechanism abruptly moves the modules to a new position and then starts to forward track (with an offset) until shadowing is an issue again. For example, the tracking mechanisms of the present invention roll off of our AOI curve again. Depending on the specific application, the offset varies by the thickness of the glass and the size of the photovoltaic strips. In an example, approximately 60 degrees is used the offset. It is to be understood that other angles may be used as well, as there are an infinite number of possible variations of tracking profiles. While the profiles are not identical, any shadowing often has some backtracking. This is true for tilted one axis, azimuth, and dual axis to name a few but not all combinations of tracking. To get the maximum amount of energy out of the system, unique tracking profiles are provided by embodiments of the present invention.

According to an embodiment, the present invention provides a system for collecting solar energy. The system includes a solar panel, the solar panel comprising a plurality of photovoltaic strips, the plurality of photovoltaic strips including a first strip and a second strip, the first strip and the second strip being substantially parallel to each other, the plurality of photovoltaic strips being electrically coupled to one another, the solar panel including a front cover member, the front cover member including a plurality of concentrator elements, the plurality of photovoltaic strips being aligned to the plurality of concentrator elements, the plurality of concentrator elements including a first concentrator element and a second concentrator element, the first concentrator element and the second concentrator element being separated by a notch, the first concentrator being associated with a first angle and a second angle, the first concentrator being configured to transmit electromagnetic waves received at the first angle to the first photovoltaic strip, the first concentrator being configured to transmit electromagnetic waves received at the second angle to the second photovoltaic strip, the second concentrator being configured to transmit electromagnetic waves received at the first angle to the second photovoltaic strip. The system also includes a sensor for determining a position for a light source. For example, the sensor can be a light sensor, GPS sensor, astronomical tacking sensors, and others. The system additionally includes a motion control module for selecting a third angle for receiving electromagnetic waves from the light source, the third angle being selected between the first angle and the second angle. Also, the system includes a motor module configured for rotating the solar panel for facing the light source at the third angle.

In a specific embodiment, the plurality of concentrator elements are integral to the front cover member, the front cover member consisting essentially of glass material, and/or other types of transparent material.

In a specific embodiment, the first concentrator member comprises a substantially spherical region, the spherical region including a flat region.

In a specific embodiment, the first angle is approximately 90 degrees and the second angle is between 40 and 75 degrees.

In a specific embodiment, the light source is the sun.

In a specific embodiment, the motion control module selects the third angle based on a time of the day.

In a specific embodiment, the solar panel is a part of solar panel array.

In a specific embodiment, the plurality of concentrator elements are integrally formed on the front cover member.

In a specific embodiment, the sensor comprises a light detector having a field of view of at least 90 degrees.

In a specific embodiment, the system comprising a base, the base being stationary.

In a specific embodiment, the front is substantially transparent and characterized by a refractive index of at least 1.4.

In a specific embodiment, the plurality of photovoltaic strips are electrical coupled to one another by an electrically conductive member.

In a specific embodiment, the plurality of photovoltaic strips are coupled to the front cover member by EVA material, and/or other types of material.

In a specific embodiment, the motion control module selects the third angle based at least on a season of the year.

In a specific embodiment, the solar panel faces the sun at the first angle in the morning and faces the sun at the second angle around noon.

According to another embodiment, the present invention provides system for collecting solar energy. The system includes a solar array comprising a first solar panel and a second solar panel, the first solar panel being at a predetermined distance from the second solar panel. The system includes a solar panel, the solar panel comprising a plurality of photovoltaic strips, the plurality of photovoltaic strips including a first strip and a second strip, the first strip and the second strip being substantially parallel to each other, the plurality of photovoltaic strips being electrically coupled to one another, the solar panel including a front cover member, the front cover member including a plurality of concentrator elements, the plurality of photovoltaic strips being aligned to the plurality of concentrator elements, the plurality of concentrator elements including a first concentrator element and a second concentrator element, the first concentrator element and the second concentrator element being separated by a notch, the first concentrator element being associated with a first angle and a second angle, the first concentrator being configured to transmit electromagnetic waves received at the first angle to the first photovoltaic strip, the first concentrator being configured to transmit electromagnetic waves received at the second angle to the second photovoltaic strip, the second concentrator being configured to transmit electromagnetic waves received at the first angle to the second photovoltaic strip. The system also includes a motion control module for determining a position for a light source and selecting a third angle for receiving electromagnetic waves from the light source, the third angle being selected between the first angle and the second angle. The system also includes a first motor module configured for rotating the first solar panel for facing the light source at the third angle.

In a specific embodiment, the first angle is associated with a first efficiency level and the second angle is associated with a second efficiency level.

In a specific embodiment, the motion control module selects the first angle if selecting the second angle causes the first solar panel to cast a predetermined amount of shadow on the second solar panel.

In a specific embodiment, the system comprises a second motor module for rotating the second solar panel for facing the light source at the third angle.

In a specific embodiment, system includes a mounting assembly for mounting the first solar panel and the second solar panel at the predetermined distance, the mounting assembly being stationary.

In a specific embodiment, the motion control module determines a solar azimuth.

In a specific embodiment, the system includes a light sensor for detecting solar position.

In a specific embodiment, the motion control module determines solar azimuth based on pre-stored data and detected solar position.

In a specific embodiment, the system includes a network interface allowing for remote control.

In a specific embodiment, the system includes a battery for energy storage.

In a specific embodiment, the system includes a user interface for configuring the motion control module.

In a specific embodiment, the system includes a plurality of tracking posts for mounting the solar panels.

In a specific embodiment, the photovoltaic strips consist of silicon or thin-film material.

In a specific embodiment, the plurality of solar panels are generally north-south oriented.

It is understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A system for collecting solar energy, the system comprising:
a solar panel, the solar panel comprising a plurality of photovoltaic strips, the plurality of photovoltaic strips including a first strip and a second strip, the first strip and the second strip being substantially parallel to each other, the plurality of photovoltaic strips being electrically coupled to one another, the solar panel including a front cover member, the front cover member including a plurality of concentrator elements, the plurality of photovoltaic strips being aligned to the plurality of concentrator elements, the plurality of concentrator elements including a first concentrator element and a second concentrator element, the first concentrator element and the second concentrator element being separated by a notch, the first concentrator being associated with a first angle and a second angle, the first concentrator being configured to transmit electromagnetic waves received at the first angle to the first photovoltaic strip, the first concentrator being configured to transmit electromagnetic waves received at the second angle to the second photovoltaic strip, the second concentrator being configured to transmit electromagnetic waves received at the first angle to the second photovoltaic strip;
a sensor for determining a position for a light source;
a motion control module for selecting a third angle for receiving electromagnetic waves from the light source, the third angle being selected between the first angle and the second angle;
a motor module configured for rotating the solar panel for facing the light source at the third angle.

2. The system of claim 1 wherein the plurality of concentrator elements are integral to the front cover member, the front cover member consisting essentially of glass material, and/or other types of transparent material.

3. The system of claim 1 wherein the first concentrator member comprises a substantially spherical region, the spherical region including a flat region.

4. The system of claim 1 wherein the first angle is approximately 90 degrees and the second angle is between 40 and 75 degrees.

5. The system of claim 1 wherein the light source is the sun.

6. The system of claim 1 wherein the motion control module selects the third angle based on a time of the day.

7. The system of claim 1 wherein the solar panel is a part of solar panel array.

8. The system of claim 1 where in the plurality of concentrator elements are integrally formed on the front cover member.

9. The system of claim 1 wherein the sensor comprises a light detector having a field of view of at least 90 degrees.

10. The system of claim 1 further comprising a base, the base being stationary.

11. The system of claim 1 wherein the front is substantially transparent and characterized by a refractive index of at least 1.4.

12. The system of claim 1 wherein the plurality of photovoltaic strips are electrical coupled to one another by an electrically conductive member.

13. The system of claim 1 wherein the plurality of photovoltaic strips are coupled to the front cover member by EVA material, and/or other types of material.

14. The system of claim 1 wherein the motion control module selects the third angle based at least on a season of the year.

15. The system of claim 1 wherein the solar panel faces the sun at the first angle in the morning and faces the sun at the second angle around noon.

16. A system for collecting solar energy, the system comprising:
a solar array comprising a first solar panel and a second solar panel, the first solar panel being at a predetermined distance from the second solar panel;
a solar panel, the solar panel comprising a plurality of photovoltaic strips, the plurality of photovoltaic strips including a first strip and a second strip, the first strip and the second strip being substantially parallel to each other, the plurality of photovoltaic strips being electrically coupled to one another, the solar panel including a front cover member, the front cover member including a plurality of concentrator elements, the plurality of photovoltaic strips being aligned to the plurality of concentrator elements, the plurality of concentrator elements including a first concentrator element and a second concentrator element, the first concentrator element and the second concentrator element being separated by a notch, the first concentrator element being associated with a first angle and a second angle, the first concentrator being configured to transmit electromagnetic waves received at the first angle to the first photovoltaic strip, the first concentrator being configured to transmit electromagnetic waves received at the second angle to the second photovoltaic strip, the second concentrator being configured to transmit electromagnetic waves received at the first angle to the second photovoltaic strip;
a motion control module for determining a position for a light source and selecting a third angle for receiving electromagnetic waves from the light source, the third angle being selected between the first angle and the second angle;
a first motor module configured for rotating the first solar panel for facing the light source at the third angle.

17. The system of claim 16 wherein the first angle is associated with a first efficiency level and the second angle is associated with a second efficiency level.

18. The system of claim 16 wherein the motion control module selects the first angle if selecting the second angle causes the first solar panel to cast a predetermined amount of shadow on the second solar panel.

19. The system of claim 16 further comprising a second motor module for rotating the second solar panel for facing the light source at the third angle.

20. The system of claim 16 further comprising a mounting assembly for mounting the first solar panel and the second solar panel at the predetermined distance, the mounting assembly being stationary.

21. The system of claim 16 wherein the motion control module determines a solar azimuth.

22. The system of claim 16 further comprising a light sensor for detecting solar position.

23. The system of claim 16 wherein the motion control module determines solar azimuth based on pre-stored data and detected solar position.

24. The system of claim 16 further comprising a network interface allowing for remote control.

25. The system of claim 16 further comprising a battery for energy storage.

26. The system of claim 16 further comprising a user interface for configuring the motion control module.

27. The system of claim 16 further comprising a plurality of tracking posts for mounting the solar panels.

28. The system of claim 16 wherein the photovoltaic strips consist of silicon or thin-film material.

29. The system of claim 16 wherein the plurality of solar panels are generally north-south oriented.
